(19) United States
(12) Patent Application Publication
(10) Pub. No.: US 2025/0227931 A1
(43) Pub. Date: Jul. 10, 2025

(54) VERTICAL NAND FLASH MEMORY DEVICE AND ELECTRONIC APPARATUS INCLUDING THE SAME

(71) Applicant: Samsung Electronics Co., Ltd., Suwon-si (KR)

(72) Inventors: Hoseok HEO, Suwon-si (KR); Hyungyung KIM, Suwon-si (KR); Jinjoo PARK, Suwon-si (KR); Minhyun LEE, Suwon-si (KR); Seonghun JANG, Suwon-si (KR); Seokhoon CHOI, Suwon-si (KR); Seungdam HYUN, Suwon-si (KR)

(73) Assignee: Samsung Electronics Co., Ltd., Suwon-si (KR)

(21) Appl. No.: 19/010,552

(22) Filed: Jan. 6, 2025

(30) Foreign Application Priority Data
Jan. 8, 2024 (KR) 10-2024-0003118

(51) Int. Cl. H10B 43/35; H10B 43/27

(52) U.S. Cl. CPC H10B 43/35; H10B 43/27

(57) ABSTRACT

Provided are a vertical NAND flash memory device and an electronic apparatus including the same. The vertical NAND flash memory device includes a plurality of cell arrays each including a channel layer, a charge trap layer which is amorphous, is arranged on the channel layer, and includes an aluminum oxide and an oxide of an element X, and a plurality of gate electrodes arranged on the charge trap layer. The element X may include Hf, Zr, La, Y, Ta, or Ga.

### CROSS-REFERENCE TO RELATED APPLICATION

This application is based on and claims priority under 35 U.S.C. § 119 to Korean Patent Application No. 10-2024-0003118, filed on Jan. 8, 2024, in the Korean Intellectual Property Office, the disclosure of which is incorporated by reference herein in its entirety.

### BACKGROUND

### 1. Field

The disclosure relates to a vertical NAND flash memory device and an electronic apparatus including the same.

### 2. Description of the Related Art

As hard disks have been replaced with solid state drives (SSD), NAND flash memory devices, which are examples of non-volatile memory devices, are now widely used. Recently, according to the miniaturization and high integration of memory devices, vertical NAND flash memory devices having a structure in which a plurality of memory cells are stacked have been developed.

In the vertical NAND flash memory devices, an increase in the stacking number of memory cells and a decrease in height thereof may cause a charge transfer between the memory cells, which may degrade the charge retention properties of the memory cells.

### SUMMARY

Provided are a vertical NAND flash memory device and an electronic apparatus including the same.

Additional aspects will be set forth in part in the description which follows and, in part, will be apparent from the description, or may be learned by practice of the presented embodiments of the disclosure.

According to an aspect of the disclosure, a vertical NAND flash memory device includes a plurality of cell arrays, each of the plurality of cell arrays including a channel layer; a plurality of gate electrodes; and a charge trap layer separating the channel layer from the plurality of gate electrodes, the charge trap layer including an amorphous material, the amorphous material including aluminum oxide and an oxide of an element X, wherein the element X includes at least one of Hf, Zr, La, Y, Ta, or Ga.

An atomic percentage (at %) of the element X may be within a range of 0 at % to 6 at %.

An atomic percentage (at %) of the oxygen included in the charge trap layer may be within a range of about 40 at % to about 55 at %.

An atomic percentage (at %) of the aluminum included in the aluminum oxide may be within a range of about 34 at % to about 40 at %.

An atomic percentage (at %) of the element X may be within a range of about 1 at % to about 4 at %.

An atomic percentage (at %) of oxygen included in the charge trap layer may be within a range of about 45 at % to about 53 at %.

An atomic percentage (at %) of aluminum included in the aluminum oxide may be within a range of about 36 at % to about 39 at %.

The amorphous material may include a first oxide layer including the oxide of the element X and a second oxide layer including the aluminum oxide alternately deposited and stacked.

A content of oxygen included in the charge trap layer may be lower than a stoichiometric oxygen demand.

The content of oxygen included in the charge trap layer may be offset by oxygen vacancies.

A ratio of the content of the oxygen included in the charge trap layer to the stoichiometric oxygen demand may be within a range of 0.93 to 1.

The charge trap layer may have a greater permittivity than a silicon nitride.

The charge trap layer may be formed by heat-treating the aluminum oxide and the oxide of the element X at about 900° C. to about 1,300° C.

Each of the plurality of cell arrays may extend vertically from a substrate.

A channel hole extending vertically from the substrate may be formed inside the channel layer.

The channel layer and the charge trap layer may have a cylindrical shape surrounding the channel hole.

The plurality of gate electrodes may be vertically spaced apart from each other such that each of the plurality of gate electrodes may be arranged to surround the change trap layer.

A tunneling dielectric layer may be arranged between the channel layer and the charge trap layer.

A barrier dielectric layer may be arranged between the charge trap layer and the plurality of gate electrodes.

According to another aspect of the disclosure, an electronic apparatus includes the vertical NAND flash memory device described above.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of a vertical NAND flash memory device according to at least one embodiment;

FIG. 2 is a cross-sectional view of a cell array illustrated in FIG. 1;

FIG. 3 is an enlarged view of a portion A of a memory cell illustrated in FIG. 2;

FIG. 4 is a diagram illustrating trap energy according to atomic percentages of an element X, aluminum, and oxygen included in a charge trap layer;

FIG. 5 is a diagram illustrating trap density according to atomic percentages of an element X, aluminum, and oxygen included in a charge trap layer;

FIG. 6A is a diagram illustrating trap energy according to atomic percentages of an element X, aluminum, and oxygen included in a charge trap layer and Experiment 1 and Experiment 2 for measuring the trap energy;

FIG. 6B is a diagram illustrating a comparison between theoretical trap energy values and trap energy values that are actually measured according to Experiments 1 and 2 of FIG. 6A;

FIG. 7 is a diagram illustrating atomic percentages of Hf and oxygen that determine optimal trap energy of a charge trap layer;

FIG. 8 is a table illustrating the trap energies of charge trap layers according to constituent materials included in the charge trap layers; and

FIG. 9 is a conceptual diagram schematically showing a device architecture which may be applied to an electronic apparatus according to at least one embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry. Additionally, whenever a range of values is enumerated, the range includes all values within the range as if recorded explicitly clearly, and may further include the boundaries of the range. Accordingly, the range of “X” to “Y” includes all values between X and Y, including X and Y.

Hereinafter, example embodiments will be described in detail with reference to the accompanying drawings. In the drawings, like reference numerals in the drawings denote like elements, and sizes of components in the drawings may be exaggerated for clarity and convenience of explanation. Meanwhile, embodiments described below are provided only as an example, and thus can be embodied in various forms.

It will be understood that when a component is referred to as being “on” or “over” another component, the component can be directly on, under, on the left of, or on the right of the other component, or can be on, under, on the left of, or on the right of the other component in a non-contact manner. It will also be understood that such spatially relative terms, such as “above”, “top”, etc., are intended to encompass different orientations of the device in use or operation in addition to the orientation depicted in the figures, and that the device may be otherwise oriented (rotated 90 degrees or at other orientations) and the spatially relative terms used herein interpreted accordingly. An expression used in the singular encompasses the expression of the plural, unless it has a clearly different meaning in the context. When a portion “includes” an element, another element may be further included, rather than excluding the existence of the other element, unless otherwise described.

The use of the terms “a” and “an” and “the” and similar referents in the context of describing embodiments (especially in the context of the following claims) are to be construed to cover both the singular and the plural. The operations of all methods described herein can be performed in any suitable order unless otherwise indicated herein or otherwise clearly contradicted by context, and embodiments are not limited to the described order of the operations.

Moreover, the terms “part,” “module,” etc. refer to a unit processing at least one function or operation, and may be implemented by processing circuitry such as a hardware, a software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc., and/or electronic circuits including said components.

The connecting lines, or connectors shown in the various figures presented are intended to represent exemplary functional relationships and/or physical or logical couplings between the various elements, and thus it should be noted that many alternative or additional functional relationships, physical connections or logical connections may be present in a practical device.

The use of any and all examples and/or exemplary language provided herein, is intended merely to better illuminate technical ideas and does not pose a limitation on the scope of embodiments unless otherwise claimed.

The reliability element which is a key requirement for vertical NAND flash memory devices is a feature concerning retention of data, i.e., characteristics allowing long-time storage of charges in a charge trap layer. When a distance between memory cells is reduced to increase the memory density in vertical NAND flash memory devices, a transfer of trapped charges may occur between the memory cells, which may lead to degradation in chare retention properties.

In vertical NAND flash memory devices, in a direction perpendicular to the charge trap layer, charges may migrate from a charge trap layer to a tunneling dielectric layer by trap-assisted tunneling or thermal emission. A degree of such charge transfer may be determined by a conduction band offset (CBO) at an interface between the charge trap layer and the tunneling dielectric layer.

In a direction parallel with the charge trap layer, a charge transfer may be caused by lateral migration due to a charge concentration gradient. The charge transfer in the direction parallel with the charge trap layer may be controlled by Poole-Frenkel tunneling.

The current density by Poole-Frenkel tunneling may be represented by Poole-Frenkel Conduction Equation (Equation 1):

$$J = q μ {N}_{c} E exp ( \frac{- q ( {E}_{r} - \sqrt{qE / π ε )}}{{κ}_{T}} ) \qquad ( equation 1 )$$

(wherein J: current density, q: electronic charge, p: carrier mobility Nc: density of states in conduction band, E: electric field, E_{T}: trap energy, ε: permittivity, k: Boltzmann constant, T: temperature).

Thereby, the charge transfer in the direction parallel with the charge trap layer due to Poole-Frenkel tunneling may be determined by trap energy (ET) and trap density (NT) in the charge trap layer. The trap energy means a voltage barrier that electrons need to pass through to migrate from one atom to another atom in a material. That is, the trap energy refers to a depth of trap state with respect to a conduction band minimum (CBM) of the material. The trap density refers to the number of charges trapped per unit volume. The trap density may be calculated by using the charge pumping method. The charge retention properties in the direction parallel with the charge trap layer may be improved by high trap energy and high trap density.

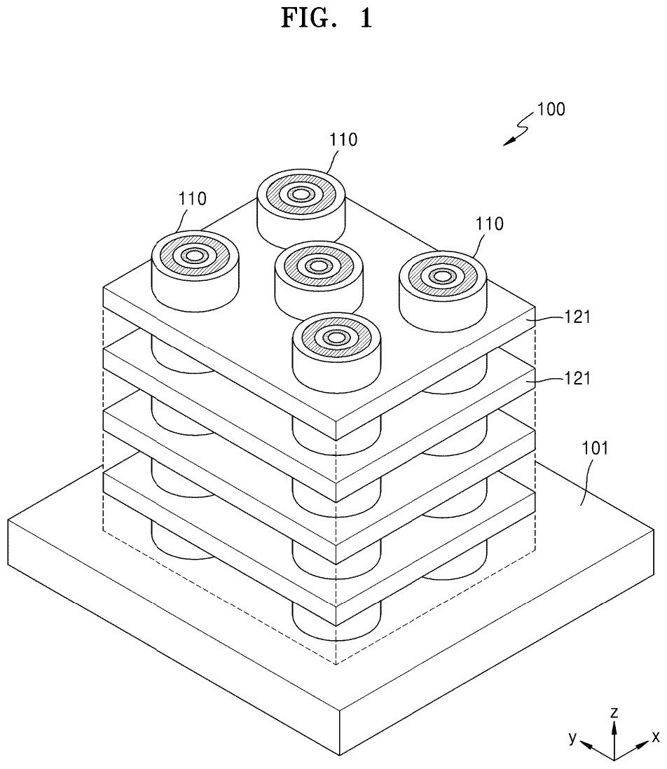

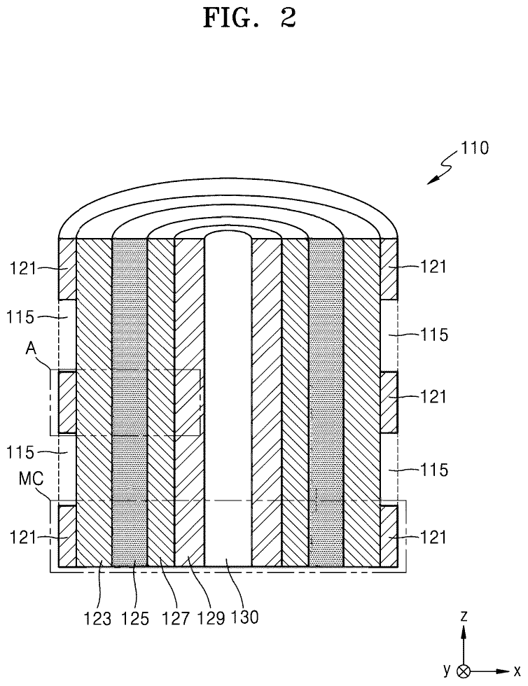

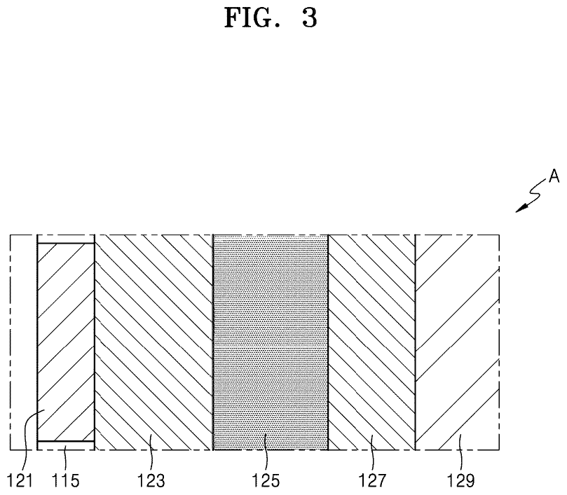

FIG. 1 is a schematic perspective view of a vertical NAND flash memory device 100 according to at least one embodiment. FIG. 2 is a cross-sectional view of the cell array 110 illustrated in FIG. 1. FIG. 3 is an enlarged view of a portion A of a memory cell MC illustrated in FIG. 2.

Referring to FIG. 1, the vertical NAND flash memory device 100 may include a plurality of cell arrays 110 arranged on a substrate 101. Each of the plurality of cell arrays 110 may be arranged to extend in a direction perpendicular to the substrate 101 (z-axis direction in FIG. 1). The plurality of cell arrays 110 may be arranged in various forms on the substrate 101. For example, the plurality of cell arrays 110 may be arranged in a grid pattern with rows and columns, a closed packed pattern with alternating rows, and/or the like.

Referring to FIGS. 2 and 3, the cell array 110 may include a plurality of memory cells MC stacked in the direction perpendicular to the substrate 101 (z-axis direction). The cell array 110 may include a plurality of gate electrodes 121 arranged apart from each other and stacked in the direction perpendicular to the substrate 101, a barrier dielectric layer 123 arranged parallel with the substrate 101 and sequentially inside the gate electrodes 121, a charge trap layer 125, a tunneling dielectric layer 127, and a channel layer 129. Each of the barrier dielectric layer 123, the charge trap layer 125, the tunneling dielectric layer 127, and the channel layer 129 may be arranged to extend perpendicularly to the substrate 101 and may be shared by the plurality of memory cells MC.

For example, each memory cell MC may include (and/or be defined by) a gate electrode 121 and the barrier dielectric layer 123, the charge trap layer 125, the tunneling dielectric layer 127, and the channel layer 129, which are arranged at a position corresponding to the gate electrodes 121. The channel layer 129 may be connected to a source and a drain, and a channel region of the channel layer 129 corresponding to the gate electrode 121 may be formed in the channel layer 129 between the source and the drain. When a certain voltage is applied to the gate electrode 121 in each memory cell MC, as charges flowing between the source and the drain (e.g., in the channel region of the channel layer 129 corresponding to the gate electrode 121) pass through the tunneling dielectric layer 127 and are trapped in the charge trap layer 125, information may be stored.

Interlayer insulating layers 115 and the gate electrodes 121 may be alternately stacked on the substrate 101 in the direction perpendicular to the substrate 101. Each interlayer insulating layer 115 and each gate electrode 121 may be arranged to be parallel (and/or substantially parallel) with the substrate 101. The substrate 101 may include various materials. For example, the substrate 101 may include a single-crystal silicon substrate, a compound semiconductor substrate, or a silicon-on-insulator (SOI) substrate; however, the disclosure is not limited thereto. In addition, the substrate 101 may further include, for example, an impurity area due to doping, an electronic device such as a transistor, a periphery circuit configured to select and control memory cells storing data, and/or the like.

The gate electrode 121 may control a corresponding channel layer 129 and may be electrically connected to a word line. The gate electrode 121 may include, for example, a metal material having excellent electric conductivity (such as gold (Au)), a metal nitride, silicon doped with impurities, two-dimensional (2D) conductive material, and/or the like. However, the foregoing is just an example, and the gate electrode 121 may further include various other materials in addition to the above. The interlayer insulating layer 115 may function as a spacer for insulation between the gate electrodes 121. The interlayer insulating layer 115 may include, for example, an electrical insulator such as a silicon oxide, a silicon nitride, etc.; however, the disclosure is not limited thereto.

A channel hole may be formed to pass through the interlayer insulating layers 115 and the plurality of gate electrodes 121 in the direction perpendicular to the substrate 101 (z-axis direction). Such channel hole may be formed to have, for example, a circular cross-section.

The barrier dielectric layer 123, the charge trap layer 125, the tunneling dielectric layer 127, and the channel layer 129 may be sequentially arranged on an inner wall of the channel hole. Each of the barrier dielectric layer 123, the charge trap layer 125, the tunneling dielectric layer 127, and the channel layer 129 may be formed to have a cylindrical shape extending in the direction perpendicular to the substrate 101. A filling insulating layer 130 may be arranged inside the channel layer 129 to fill the channel hole. The filling insulating layer 130 may include, for example, a silicon oxide, air, etc.; however, the disclosure is not limited thereto.

The channel layer 129 may include a semiconductor material. For example, the channel layer 129 may include an elemental and/or a compound semiconductor, for example, at least one of Si, Ge, SiGe, group III-V semiconductors, etc. In addition, the channel layer 129 may include, for example, an oxide semiconductor, a nitride semiconductor, an oxynitride semiconductor, a 2D semiconductor material, quantum dots, an organic semiconductor, and/or the like. The oxide semiconductor may include, for example, InGaZnO, etc., and the 2D material may include, for example, a semiconductor transition metal dichalcogenide (TMD) or graphene, and the quantum dots may include a colloidal quantum dots (QDs), a nanocrystal structure, etc. However, the foregoing is just an example, and the disclosure is not limited thereto.

The channel layer 129 may further include a dopant. The dopant may include a p-type dopant or an n-type dopant. For example, wherein the channel layer 129 includes group IV element (e.g., Si and/or Ge) the p-type dopant may include a group III element, such as B, Al, Ga, In, etc., and the n-type dopant may include a group V element, such as P, As, Sb, etc.

The barrier dielectric layer 123, the charge trap layer 125, and the tunneling dielectric layer 127 may be arranged between the channel layer 129 and the plurality of gate electrodes 121. The barrier dielectric layer 123 may be arranged on the inner wall of the channel hole to be in contact with the interlayer insulating layers 115 and the gate electrodes 121. The barrier dielectric layer 123 may include, for example, an electrical insulator (e.g., a silicon oxide or a metal oxide); however, the disclosure is not limited thereto. The tunneling dielectric layer 127 is a layer where the tunneling of charges occurs and may include, for example, an electrical insulator (e.g., a silicon oxide or a metal oxide); however, the disclosure is not limited thereto.

The charge trap layer 125 may be arranged between the barrier dielectric layer 123 and the tunneling dielectric layer 127. The charge trap layer 125 may include an aluminum oxide and an oxide of an element X. For the example, the element X may include Hf, Zr, La, Y, Ta, or Ga. However, the disclosure is not limited thereto.

As a constituent material of the charge trap layer 125, the charge trap layer 125 may include a material selected for decreasing a driving voltage by using the field effect caused by high-k and improving the memory charge retention through a high charge trap energy and density.

More specifically, the charge trap layer 125 may include an amorphous material including aluminum oxide and a metal oxide having a greater permittivity than a silicon oxide. For example, The charge trap layer 125 may include an amorphous mixture of aluminum oxide and an oxide of an element X, and the element X may include Hf, Zr, La, Y, Ta, or Ga. In other words, the charge trap layer 125 may be at least one of HfAlO, ZrAlO, LaAlO, YAlO, TaAlO, and/or GaAlO. However, the disclosure is not limited thereto.

The charge trap layer may be formed by alternately depositing the aluminum oxide and the oxide of the element X. In this regard, an aluminum oxide layer and an oxide layer of the element X may be included a first oxide layer and a second oxide, respectively, and the first oxide layer and the second oxide layer may be deposited and stacked alternately. For example, when the charge trap layer 125 is HfAlO, the trap energy may increase 2.5 times, compared to a comparative example including SiN.

When the element X included in the charge trap layer 125 is Hf, the atomic percentage (at %) of the element X may broadly be greater than 0 at % but not more than 6 at %, the atomic percentage of oxygen of the aluminum oxide included in the charge trap layer 125 may broadly be 40 at % to 55 at %, and the atomic percentage of aluminum of the aluminum oxide may broadly be 34 at % to about 40 at %.

For example, when the element X included in the charge trap layer 125 is Hf, the atomic percentage (at %) of the element X may conservatively be within of range of 1 at % to 4 at %, the atomic percentage of oxygen of the aluminum oxide included in the charge trap layer 125 may conservatively be within of range of 45 at % to 53 at %, and the atomic percentage of aluminum of the aluminum oxide may conservatively be within of range of 36 at % to about 39 at %.

The atomic percentage of the charge trap layer 125 above may be determined according to the element X, and the atomic percentage of oxygen and aluminum may vary according to a type of the element X.

For example, when the element X is Zr, the atomic percentage of the element X may conservatively be within of range of 1 at % to 6 at %, the atomic percentage of oxygen may be within of range of 57 at % to 60 at %, and the atomic percentage of aluminum may be within of range of 34 at % to 39 at %.

When the element X is Zr, the atomic percentage of the element X may broadly be greater than 0 at % but not more than 8 at %, the atomic percentage of oxygen may be within of range of 55 at % to 60 at %, and the atomic percentage of aluminum may be 32 at % to 40 at %.

When the element X is La, the atomic percentage of the element X may conservatively be within of range of 0.5 at % to 3 at %, the atomic percentage of oxygen may be within of range of 57 at % to 60 at %, and the atomic percentage of aluminum may be within of range of 37 at % to 39.5 at %.

When the element X is La, the atomic percentage of the element X may broadly be greater than 0 at % but not more than 4 at %, the atomic percentage of oxygen may be within of range of 55 at % to 60 at %, and the atomic percentage of aluminum may be within of range of 36 at % to 40 at %.

When the element X is yttrium (Y), the atomic percentage of the element X may conservatively be within of range of 0.5 at % to 3 at %, the atomic percentage of oxygen may be within of range of 57 at % to 60 at %, and the atomic percentage of aluminum may be within of range of 37 at % to 39.5 at %.

When the element X is Y, the atomic percentage of the element X may broadly be greater than 0 at % but not more than 4 at %, the atomic percentage of oxygen may be within of range of 55 at % to 60 at %, and the atomic percentage of aluminum may be within of range of 36 at % to 40 at %.

When the element X is Ga, the atomic percentage of the element X may conservatively be within of range of 0.5 at % to 2.5 at %, the atomic percentage of oxygen may be within of range of 57 at % to 60 at %, and the atomic percentage of aluminum may be within of range of 37.5 at % to 39.5 at %.

When the element X is Ga, the atomic percentage of the element X may broadly be greater than 0 at % but not more than 3.5 at %, the atomic percentage of oxygen may be within of range of 55 at % to 60 at %, and the atomic percentage of aluminum may be within of range of 36.5 at % to 40 at %.

When the element X is Ta, the atomic percentage of the element X may conservatively be within of range of 0.5 at % to 2 at %, the atomic percentage of oxygen may be within of range of 57 at % to 60 at %, and the atomic percentage of aluminum may be within of range of 38 at % to 39.5 at %.

When the element X is Ta, the atomic percentage of the element X may broadly be 0.5 at % to 2 at %, the atomic percentage of oxygen may be within of range of 55 at % to 60 at %, and the atomic percentage of aluminum may within of range of be 37 at % to 40 at %.

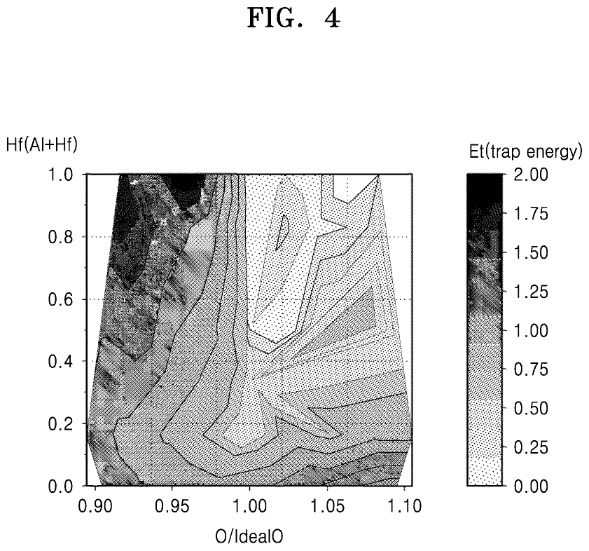

FIG. 4 is a diagram illustrating trap energy according to atomic percentages of the element X, aluminum, and oxygen included in the charge trap layer.

Referring to FIG. 4, the x axis represents a section of the ratio of the content of oxygen (“O”) included in the charge trap layer to the stoichiometric oxygen demand (“Ideal O”) from 0.90 to 1.10, and the y axis represents a section of the ratio of the amount of Hf to Hf+Al from 0.0 to 1.0 when the element X is Hf.

The trap energy means a voltage barrier that electrons need to pass through to migrate from one atom to another atom in a material. High trap energy may facilitate blocking of charge transfer between a plurality of memory cells and may prevent and/or mitigate degradation in memory retention.

The actual content of oxygen of the charge trap layer 125 including the element X oxide and the aluminum oxide may be low, compared to the stoichiometric oxygen demand, and the actual oxygen content may be offset by oxygen vacancies. More specifically, a ratio of the content of oxygen included in the charge trap layer 125 to the stoichiometric oxygen demand may be 0.93 or more and less than 1. In other words, a ratio of the content of oxygen to the stoichiometric oxygen demand in the at least one example embodiment, may be within a range of 0.93 to 1. However, the disclosure is not necessarily limited thereto.

A ratio of the content of HF to the content of Hf+Al of the charge trap layer 125 including the element X oxide and the aluminum oxide may be 0.83 or greater and less than 1.0. However, the disclosure is not necessarily limited thereto.

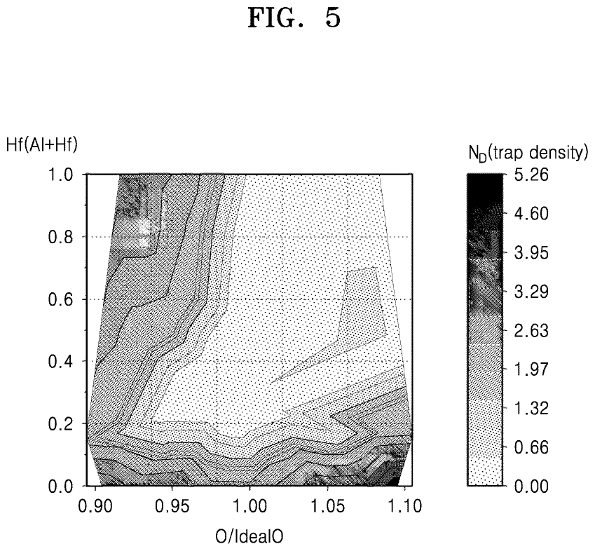

FIG. 5 is a diagram illustrating trap density according to atomic percentages of the element X, aluminum, and oxygen included in the charge trap layer.

The trap density refers to the number of charges trapped per unit volume. The trap density may be calculated by using the charge pumping method described above. The charge retention properties may be improved by high trap energy and high trap density.

Referring to FIG. 5, the x axis represents a section of the ratio of the content of oxygen included in the charge trap layer 125 to the stoichiometric oxygen demand from 0.90 to 1.10, and the y axis represents a section of the ratio of the amount of Hf to Hf+Al from 0.0 to 1.0 when the element X is Hf.

The actual content of oxygen of the charge trap layer 125 including the element X oxide and the aluminum oxide may be low, compared to the stoichiometric oxygen demand, and the actual oxygen content may be determined by oxygen vacancies. More specifically, the ratio of the content of oxygen included in the charge trap layer 125 to the stoichiometric oxygen demand may be 0.93 or more and less than 1. In other words, a ratio of the content of oxygen to the stoichiometric oxygen demand in the at least one example embodiment, may be within a range of 0.93 to 1. However, the disclosure is not limited thereto, and the ratio of the content of the element X to X+Al may vary according to a type of the element X.

The ratio of the content of HF to the content of Hf+Al of the charge trap layer 125 including the element X oxide and the aluminum oxide may be 0.83 or greater and less than 1.0. However, the disclosure is not limited thereto, and the ratio of the content of the element X to X+Al may vary according to a type of the element X.

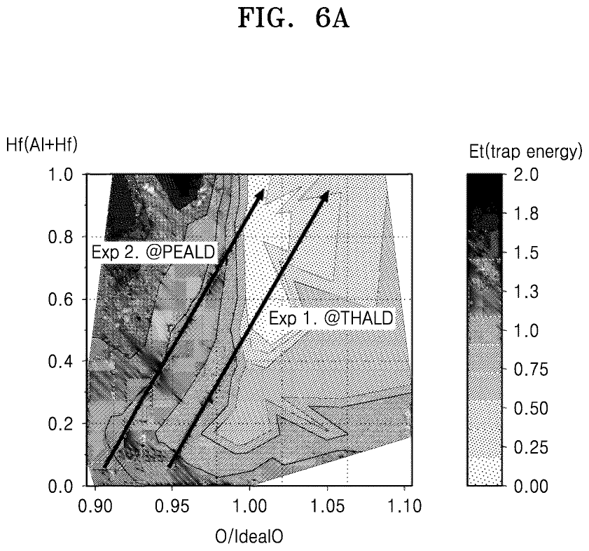

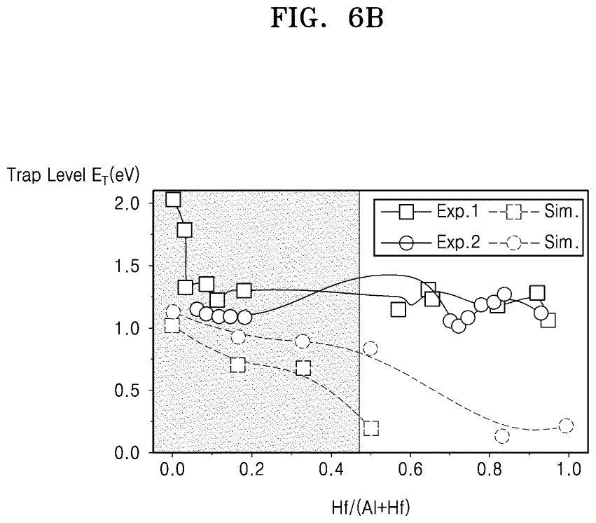

FIG. 6A is a diagram illustrating trap energy according to atomic percentages of the element X, aluminum, and oxygen included in the charge trap layer and Experiment 1 and Experiment 2 for measuring the trap energy.

Referring to FIG. 6A, when the element X included in the charge trap layer 125 is Hf, the y axis represents a section of the ratio of the amount of Hf to Hf+Al from 0.0 to 1.0, and the x axis represents a section of the ratio of the content of oxygen included in the charge trap layer 125 to the stoichiometric oxygen demand from 0.90 to 1.10. The highs and the lows of the trap energy are shown for each area. In addition, through Experiment 1 (exp1) and Experiment 2 (exp2), the atomic percentage of oxygen corresponding to the atomic percentage of Hf may be determined, and measured values of the trap energy according to an amount of HF in comparison with Hf+Al may be identified. Experiment 1 used thermal atomic layer deposition (THALD), and Experiment 2 used plasma enhanced ALD (PEALD). The measured values of the trap energy according to Experiment 1 and Experiment 2 and the theoretical trap energy values are shown in FIG. 6B.

FIG. 6B is a diagram illustrating comparison between theoretical trap energy values (“Sim”) and trap energy values that are actually measured according to Experiments 1 and 2 of FIG. 6A (“Exp.1” and “Exp.2,” respectively).

Referring to FIG. 6B, the comparative distribution of the actually measured trap energy values and the theoretical trap energy values may be identified, and in a section representing the ratio of the amount of Hf to Hf+Al from greater than 0 and less than 0.5, the actually measured trap energy values tend to mostly correspond to the theoretical trap energy values. More specifically, the theoretical trap energy values and the actually measured trap energy values show high consistency in a section where the amount of Hf is less in comparison with Hf+Al, whereas in a section where the amount of Hf is great in comparison with Hf+Al, the crystallization between Hf and Al results in significantly low consistency. To enhance the charge retention properties of the charge trap layer, the atomic percentage range of the section where the actually measured trap energy value matches the theoretical trap energy values according to Experiments 1 and 2 may be valid.

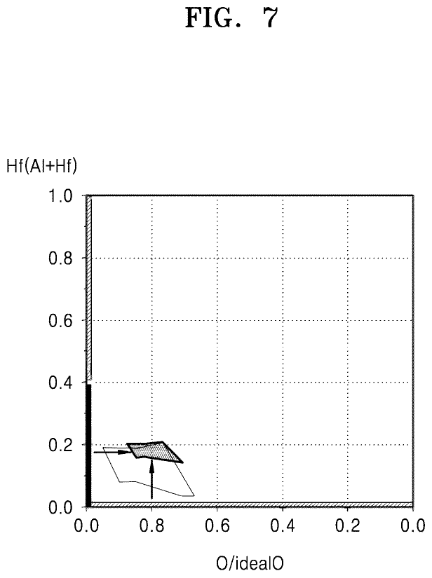

FIG. 7 is a diagram illustrating atomic percentages of Hf and oxygen that determine optimal trap energy of the charge trap layer.

Referring to FIG. 7, the x axis represents a ratio of the content of oxygen to the stoichiometric oxygen demand, and the y axis represents the relative content of Hf to Hf+Al. The trap energy of the charge trap layer 125 may be highest when the ratio of the oxygen to the stoichiometric oxygen demand is about 0.90 to about 0.99, and the ratio of the content of Hf to Hf+Al is about 0.15 to about 0.20, and the charge retention properties of the memory cell according to the disclosure may be enhanced in the aforementioned ranges. However, the forgoing ranges may be determined only when the element X is Hf. Accordingly, the disclosure is not limited thereto, and the ratio of the content of the element X to X+Al may vary according to a type of the element X.

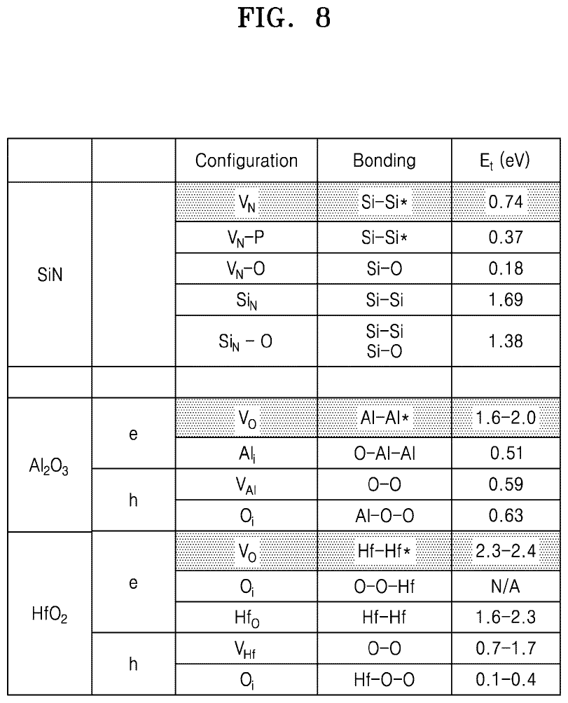

FIG. 8 is a table illustrating the trap energies of charge trap layers according to constituent materials included in the charge trap layers.

Referring to FIG. 8, the trap energy of a charge trap layer including a hafnium (Hf) oxide may be high, compared to the charge trap layer 125 including a silicon nitride or an aluminum oxide. For example, when the constituent material of the charge trap layer 125 is SiN, the trap energy of the charge trap layer may be about 0.18 to about 0.74; however, when the constituent material of the charge trap layer 125 is HfO2, the trap energy of the charge trap layer 125 may be about 2.3 to about 2.4. Accordingly, the trap energy of the charge trap layer may significantly increase, compared to the existing SiN material, and as such high trap energy may strengthen the characteristics of trapping charges due to atomic defects, the charge retention properties of the memory device may be improved. As described above, an increase in trap energy may be caused by vacancies of anions of constituent materials.

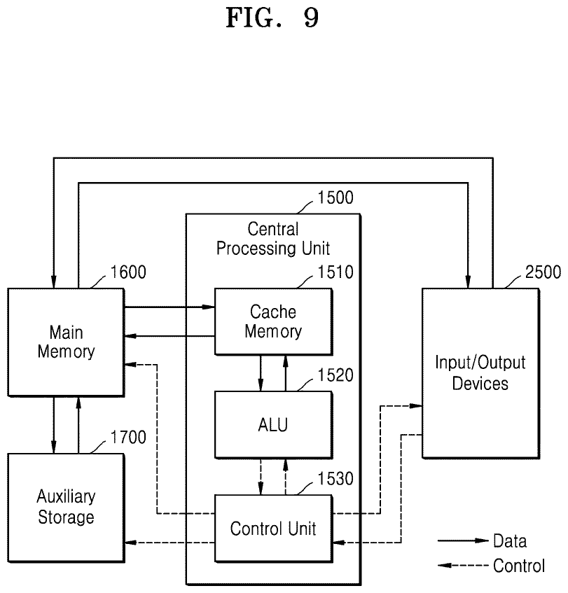

The vertical NAND flash memory device 100 described above may be used for data storage in various electronic apparatuses. FIG. 9 is a conceptual diagram schematically showing a device architecture which may be applied to an electronic apparatus according to some embodiments.

Referring to FIG. 9, a cache memory 1510, an ALU 1520, and a control unit 1530 may constitute a central processing unit (CPU) 1500, and the cache memory 1510 may include static random access memory (SRAM). A main memory 1600 and an auxiliary storage 1700 may be provided separately from the CPU 1500. The main memory 1600 may include a dynamic random access memory (DRAM) device, and the auxiliary storage 1700 may include the vertical NAND flash memory device 100 described above.

In some cases, the device architecture may be implemented in a form in which computing unit devices and memory unit devices are adjacent to each other on a single chip without separating sub-units. Although some embodiments have been described, the embodiments are provided only as an example, and thus various modifications may be made by a person skilled in the art.

The vertical NANS flash memory device according to at least one embodiment may include the charge trap layer which is amorphous and includes an aluminum oxide and an oxide of the element X, and the atomic percentages of aluminum, the element X, and oxygen may be limited to a certain range. In this regard, the driving voltage may be decreased by forming the charge trap layer with an aluminum oxide and an element X oxide which have a higher permittivity than a silicon nitride, and due to higher trap energy as compared to that of the silicon nitride, the charge transfer in a direction perpendicular to the charge trap layer and in a direction parallel with the charge trap layer may be suppressed. As such, the charge trap layer having an atomic percentage limited to a certain range may increase the trap energy and the trap density, and by suppressing the transfer of trapped charges between memory cells, the charge retention properties may be enhanced. Accordingly, a reduced threshold voltage may improve memory operation characteristics.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A vertical NAND flash memory device comprising:
a plurality of cell arrays, each of the plurality of cell arrays including
a channel layer;
a plurality of gate electrodes; and
a charge trap layer separating the channel layer from the plurality of gate electrodes, the charge trap layer including an amorphous material, the amorphous material including aluminum oxide and an oxide of an element X, wherein the element X includes at least one of Hf, Zr, La, Y, Ta, or Ga.

2. The vertical NAND flash memory device of claim 1, wherein an atomic percentage (at %) of the element X is greater than 0 at % and 6 at % or less.

3. The vertical NAND flash memory device of claim 1, wherein an atomic percentage (at %) of oxygen included in the charge trap layer is within a range of about 40 at % to about 55 at %.

4. The vertical NAND flash memory device of claim 3, wherein the atomic percentage (at %) of the oxygen included in the charge trap layer is within a range of about 45 at % to about 53 at %.

5. The vertical NAND flash memory device of claim 1, wherein an atomic percentage (at %) of aluminum included in the aluminum oxide is within a range of about 34 at % to about 40 at %.

6. The vertical NAND flash memory device of claim 5, wherein the atomic percentage (at %) of the aluminum included in the aluminum oxide is within a range about 36 at % to about 39 at %.

7. The vertical NAND flash memory device of claim 1, wherein an atomic percentage (at %) of the element X is within a range of about 1 at % to about 4 at %.

8. The vertical NAND flash memory device of claim 1, wherein the amorphous material includes a first oxide layer including the oxide of the element X and a second oxide layer including the aluminum oxide alternately deposited and stacked.

9. The vertical NAND flash memory device of claim 1, wherein a content of oxygen included in the charge trap layer is lower than a stoichiometric oxygen demand.

10. The vertical NAND flash memory device of claim 9, wherein the content of the oxygen included in the charge trap layer is offset by oxygen vacancies.

11. The vertical NAND flash memory device of claim 9, wherein a ratio of the content of the oxygen included in the charge trap layer to the stoichiometric oxygen demand is within a range of 0.93 to 1.

12. The vertical NAND flash memory device of claim 1, wherein a permittivity of the charge trap layer is greater than a permittivity of silicon nitride.

13. The vertical NAND flash memory device of claim 1, wherein the charge trap layer is formed by heat-treating the aluminum oxide and the oxide of the element X.

14. The vertical NAND flash memory device of claim 1, wherein each of the plurality of cell arrays extend vertically from a substrate.

15. The vertical NAND flash memory device of claim 14, further comprise:
a channel hole defined by the channel layer and extending vertically from the substrate.

16. The vertical NAND flash memory device of claim 15, wherein the channel layer and the charge trap layer are each have a cylindrical shape surrounding the channel hole.

17. The vertical NAND flash memory device of claim 14, wherein the plurality of gate electrodes are vertically spaced apart from each other such that each of the plurality of gate electrodes surrounds a region of the charge trap layer.

18. The vertical NAND flash memory device of claim 1, further comprising:
a tunneling dielectric layer between the channel layer and the charge trap layer.

19. The vertical NAND flash memory device of claim 1, further comprising:
a barrier dielectric layer between the charge trap layer and the plurality of gate electrodes.

20. An electronic apparatus comprising:
the vertical NAND flash memory device of claim 1.
